(19) United States
(12) Patent Application Publication
(10) Pub. No.: US 2025/0287654 A1
(43) Pub. Date: Sep. 11, 2025

(54) III-NITRIDE TRANSISTOR COMPRISING A PLURALITY OF ISOLATION REGIONS

(71) Applicant: Cambridge GaN Devices Limited, Cambridge (GB)

(72) Inventor: Florin UDREA, Cambridge (GB)

(21) Appl. No.: 18/596,997

(22) Filed: Mar. 6, 2024

(51) Int. Cl. H01L 29/06; H01L 29/20; H01L 29/778

(52) U.S. Cl. CPC H10D 62/116; H10D 30/475; H10D 62/8503

(57) ABSTRACT

Described herein is a power transistor comprising: a source terminal; a drain terminal; a gate terminal; a heterojunction formed between two III-nitride semiconductor layers, the heterojunction being configured to allow the formation of a two-dimensional carrier gas at the heterojunction and thereby define an active area of the power transistor; and a plurality of isolation regions located inside a boundary of the active area, the plurality of isolation regions being configured to prevent the formation of the two-dimensional carrier gas inside the plurality of isolation regions; wherein the source terminal, the drain terminal, and the gate terminal are laterally spaced apart in a first direction, the gate terminal being located between the source terminal and the drain terminal; and wherein the isolation regions are laterally spaced apart from one another in a second direction, perpendicular to the first direction.

### TECHNICAL FIELD

The present disclosure relates to a III-nitride transistor, such as a high-electron-mobility transistor (HEMT), in particular a III-nitride transistor comprising a plurality of isolation regions.

### BACKGROUND

Gallium Nitride (GaN) is a wide band gap material with properties that make it a suitable candidate for use in several fields of application (e.g. radio-frequency electronics, opto-electronics, power electronics) which require solid-state devices.

GaN technology allows transistors with high electron mobility and high saturation velocity to be designed. These properties of GaN have made it a good candidate for high-power and high-temperature microwave applications, for example radar and cellular communications systems. As systems expand in subscribers and desired capacity, interest in increasing their operating frequency and power has grown correspondingly. Higher frequency signals can carry more information (bandwidth) and allow for smaller antennas with very high gain.

Additionally, GaN with its wide bandgap offers the potential for emitting light at higher frequencies for example the green, blue, violet, and ultraviolet portions of the electromagnetic spectrum.

In the last decade, Gallium Nitride (GaN) has increasingly been considered as a very promising material for use in the field of power devices. The application areas range from portable consumer electronics, solar power inverters, electric vehicles, and power supplies. The wide band gap of the material (Eg=3.39 eV) results in high critical electric field (Ec=3.3 MV/cm) which can lead to the design of devices with a shorter drift region, and therefore lower on-state resistance if compared to a silicon-based device with the same breakdown voltage.

The use of an Aluminium Gallium Nitride (AlGaN)/GaN heterostructure also allows the formation of a two-dimensional electron gas (2DEG) at the hetero-interface where carriers can reach very high mobility (μ=2000 cm²/(Vs)) values. In addition, the piezopolarization charge present at the AlGaN/GaN heterostructure, results in a high electron density in the 2DEG layer (e.g. 1×10¹³ cm⁻²). These properties allow the development of High Electron Mobility Transistors (HEMTs) and Schottky barrier diodes with very competitive performance parameters. An extensive amount of research has focused on the development of power devices using AlGaN/GaN heterostructures.

One of the limitations of GaN HEMTs in the high power domain is the relatively poor short circuit capability. The endurance time depends on the ability of the device to tolerate a hot spot which develops during short-circuit, which in turn can lead to degradation of the metal layers above. Unlike in vertical devices, the hotspot in GaN HEMTs is located in the GaN/AlGaN layer near the surface in the vicinity of the gate and often in the vicinity of the field plates.

The traditional methods for short-circuit protection in silicon-based power devices such as IGBTs, by using external circuits for example a desaturation circuit which senses when the device is in saturation have a delay time of in the range of 2-10 μs, which may be too high for GaN HEMTs to survive [1]. GaN HEMTs could fail under short circuit condition at high dc-link voltages in several hundred nanoseconds [2]. The shorter fail times for power GaN HEMTs, compared to other competing technologies such as IGBTs and SiC MOSFETs, is associated with a presence of a strong lateral electric field near the gate/source field plate and the position of the hotspot very close to the semiconductor surface.

Methods of short circuit detection may involve current or voltage sensing, which may have advantages and disadvantages. A shunt current-sensing resistor adds additional parasitic inductance into the circuit, which can negatively affect the switching performance of the GaN HEMTs as well as the on-state losses, due to the presence of an extra series resistance. Voltage sensing across common source inductance (or resistance) is not practical for GaN, as active steps are taken to reduce stray inductance in a GaN circuit to improve switching performance and at the same time does not compromise on-state losses. Therefore, alternative methods for short-circuit and overcurrent protection are desirable for GaN devices. Recent research proposes a discrete short-circuit/overcurrent circuit for protection, but they are either limited to low-power circuits or require components that are not practically feasible. Monolithic integration of such functionality rather than a discrete implementation would allow a reduction in the overall system size/costs, a reduction in the bill of material and would lead to improved performance through the reduction of parasitic components associated with the interconnections between discrete devices.

U.S. Pat. No. 10,818,786, the contents of which are hereby incorporated by reference, provides an over-current protection and sensing circuitry utilizing a current sense transistor (Sense HEMT) that may be integrated monolithically with the main power switch. The Sense HEMT can communicate with a Miller clamp to lower the voltage on the gate of the GaN power HEMT.

Nonetheless, monolithic integration of a sense and protection circuit has its own practical challenges. The absence of mature p-channel devices in GaN HEMT processes and the device instabilities associated with GaN HEMTs can increase the difficulty of designing complex circuits in GaN.

### SUMMARY

The present disclosure provides a way to increase the endurance time of a III-nitride transistor (e.g. high electron mobility transistor, HEMT) in a short circuit, and/or overcurrent, condition.

A “III-nitride” transistor (e.g. HEMT), device, circuit (e.g. integrated circuit), layer, or region, as used herein, may refer generally to a device or part of a device based on, or comprising, the group III-nitride family of materials, including GaN, AlGaN, AlN, InN, and alloys thereof.

According to the present disclosure, there is provided a transistor with a segmented active gate (e.g. a p-GaN active gate), which may exhibit a lower saturation current for an equivalent Ron resistance compared to known devices.

Described herein is a high voltage and/or power transistor (also referred to herein as a “power transistor”) comprising: a heterojunction formed between two III-nitride semiconductor layers, the heterojunction being configured to allow the formation of a two-dimensional carrier gas (e.g. a two-dimensional electron gas, 2DEG, or a two-dimensional hole gas, 2DHG) at the heterojunction and thereby define an active area of the power transistor; and a plurality of isolation regions located inside a boundary of the active area, the plurality of isolation regions being configured to prevent the formation of the two-dimensional carrier gas inside said isolation regions.

The boundary of the active area of the power transistor may also be defined by a region of isolation enclosing a region of active area of the power transistor. Such a region may be referred to as a boundary region, or a boundary isolation region. The boundary (isolation) region may be configured to prevent the formation of the two-dimensional carrier gas within the boundary isolation region, thereby defining a boundary of the active area of the power transistor.

Advantageously, the power transistor according to the present disclosure may exhibit a lower saturation current for a given Ron resistance compared to devices without isolation regions as described herein. A transistor or device according to the present disclosure may therefore be capable of withstanding heating due to a short circuit/overcurrent event for a longer time than known III-nitride based devices (e.g. for a time comparable to devices based on Si or SiC), extending the amount of time available to act to protect the device (e.g. by turning off the device via a protection circuit or the like).

It will be understood that the isolation regions are physically located within the boundary of the active area, but that the two-dimensional carrier gas is prevented from forming at the isolation regions. The isolation regions may therefore be said to interrupt the active area.

Preferably the plurality of isolation regions are located under the gate terminal, or in the vicinity of the gate or source, or in the space between the gate and source.

Without wishing to be bound by theory, removing (e.g. periodically) the ability to form the two-dimensional carrier gas may have a greater effect on the saturation current than on the on-state current, because the majority of the potential drop between the drain and source terminal occurs near the gate (on the drain side) when the device is operating in saturation. The carrier velocity saturates in two dimensional carrier gas near the gate region. A reduction in the gate width/perimeter results in a larger proportional decrease in the saturation current than an increase in the on-state resistance. The isolation regions described herein may therefore reduce (e.g. halve) the effective gate width/perimeter while maintaining largely the same drift region width.

The power transistor may comprise a HEMT.

In an example, the heterojunction is formed between a GaN layer and an AlGaN layer and the two dimensional carrier gas is a two dimensional electron gas. In some examples, the two-dimensional electron gas may be formed when the transistor is in an on-state. In some examples, the heterojunction may be said to “comprise” the two-dimensional electron gas.

The power transistor may comprise a source terminal and a drain terminal.

The power transistor may comprise at least one gate terminal (also referred to herein as a “first gate terminal”).

The source terminal and the drain terminal may be spaced apart in a first direction.

The gate terminal may be located between the source terminal and the drain terminal.

The power transistor may comprise a plurality of isolation regions. The plurality of isolation regions may be spaced apart from one another in a second direction, perpendicular to the first direction.

In some examples, the power transistor is a lateral device. That is, the source terminal, the drain terminal, and/or the gate terminal are laterally spaced apart in a first dimension, which may correspond to the first direction. The isolation regions may therefore be spaced apart from one another in a second dimension, corresponding to the second direction. (A “dimension” may correspond to, e.g., any of x, y, or z in a Cartesian coordinate system.)

In some examples, the “first direction” may refer to a current flow direction (i.e. a direction in which current is configured to flow in the device—e.g. between the source terminal to the drain terminal. The isolation regions may be laterally spaced apart from one another in a direction perpendicular to the current flow direction (the “second direction”).

In some examples, the power transistor comprises a hexagonal cell (described in more detail below). In a power transistor comprising a hexagonal cell, a hexagonal source terminal may be formed around an outside edge of the cell, a drain terminal may be at or near a center of the cell, while a hexagonal gate terminal may surround the drain terminal and be positioned between the source terminal and the drain terminal. The source terminal, the drain terminal, and/or the gate terminal may surround a same axis, although it will be understood that in some examples they may not be exactly coaxial or concentric.

Therefore, it will be understood that, in some examples, the first direction may correspond to a generally radial direction, and the second direction may correspond to a direction parallel to an edge of a hexagonal terminal.

In some examples, the isolation regions are adjacent a gate terminal of the power transistor. For example, the gate terminal may comprise a metallization layer formed directly on the AlGaN layer or on one or more doped III-nitride regions or layers (e.g. a p-type region or layer) placed on top of AlGaN, which may in some examples described herein be referred to as a p-GaN gate. The isolation region(s) may be arranged to create islands where the two dimensional electron gas is not present. In some embodiments of this invention (and examples given) the isolation regions may be arranged to separate, or segment the doped III-nitride region(s) or layer(s) (i.e. there may be an isolation region between two of the doped III-nitride regions).

The doped III-nitride region(s) or layer(s) may be, in general, of an opposite conductivity type to the conductivity type of the two-dimension carrier gas.

The gate terminal (metallization) may be disposed on a single doped III-nitride region, or the gate terminal (metallization) may be disposed across a plurality of (separated/segmented) doped III-nitride regions.

In some examples (e.g. in the case of a hexagonal cell) the isolation regions may be located at corners of the gate terminal, which may be a hexagonal gate terminal.

In some examples, the isolation regions are between the source terminal and the gate terminal of the power transistor. Advantageously, this may result in an increase in the series source resistance of the device, which may be an effective way to decrease the saturation current and thus increase the ability of the transistor to withstand a short-circuit or overcurrent event. The extra resistance placed in series with the source is more effective in reducing the saturation current than an equivalent extra resistance placed in series with the drain. Both would increase by the same amount the on-state resistance between the source and the drain, but the voltage drop on the series source resistance would raise the source potential which in turn would decrease the effective gate to source voltage applied to the HEMT, which in turn would lead to an additional decrease in the saturation current.

In some examples, the isolation regions are adjacent to the source terminal of the power transistor, which may result in a more compact device. In some examples, the isolation regions are located under the source terminal (e.g. under a source terminal metallization) or at least under part of the source terminal. In some examples (e.g. in the case of a hexagonal cell), the isolation regions may be located at corners of the source terminal, which may be a hexagonal source terminal.

In some examples, the power transistor comprises a first gate terminal and a second gate terminal. At least one isolation region may be located between the first gate terminal and the second gate terminal, effectively separating the first gate terminal from the second gate terminal and allowing such gate terminals to be biased with different potentials. For example, the at least one isolation region may separate a first doped III-nitride region on which the first gate terminal (metallization) is disposed from a second doped III-nitride region on which the second gate terminal (metallization) is disposed. For example, the at least one isolation region may segment a doped III-nitride region into a first doped III-nitride region and a second III-nitride region. The first gate terminal and the second gate terminal may alternate in a second direction (i.e. may be interlaced in the second direction)

In a particular example described herein, a HEMT may comprise: an active area comprising a III-nitride heterojunction (e.g. formed between a GaN and AlGaN layer), the heterojunction being configured to allow the formation of a two-dimensional electron gas at the heterojunction; a source terminal operatively connected to the active area; a drain terminal operatively connected to the active area; a first p-type doped III-nitride region and a second p-type doped III-nitride region, the first and second p-type doped III-nitride regions being disposed within a boundary of the active area above the heterojunction (Above AlGaN layer); and a first gate terminal disposed on the first p-type doped III-nitride region; a second gate terminal disposed on the second p-type doped III-nitride region. The first and second p-type doped III-nitride regions may be separated (e.g. segmented) by an isolation region along the gate width dimension (i.e. the dimension perpendicular to the drain-source dimension), the isolation region being configured to prevent the formation of the two-dimensional electron gas inside the isolation region.

In general, it will be understood that a transistor (e.g. HEMT) comprises a gate. A gate terminal as described herein may be operatively connected to the gate of the transistor. For example, a first gate terminal may be operatively connected to a first gate of the transistor, and a second gate terminal may be operatively connected to a second gate of the transistor.

In some examples of a power transistor (e.g. HEMT) comprising a first gate terminal and a second gate terminal as described herein, the first gate is configured to operate with a gate-source potential above a threshold voltage of the power transistor during forward conduction (i.e. when a potential at the drain terminal is higher than a potential at the source terminal), and the second gate is configured to be grounded or to operate with a gate-source potential above the threshold voltage of the power transistor during reverse conduction (i.e. when the potential at the drain terminal is lower than the potential at the source terminal). This is particularly advantageous to ensure low-on-state losses both in forward and reverse conduction modes of operation, while also ensuring good short-circuit endurance.

In some examples, a device may comprise the power transistor (HEMT) described herein, and may further comprise one or more interface circuits connected to the first gate terminal and/or the second gate terminal. For example, one interface circuit may be connected to both the first and second gate terminals, or a first interface circuit may be connected to the first gate terminal, and a second interface circuit may be connected to the second gate terminal. The interface circuit(s) may be monolithically integrated with the power transistor (HEMT), e.g. integrated on a same III-nitride chip as the power transistor (HEMT), or the interface circuit(s) may be provided externally. In some examples described herein, the interface circuit(s) may be referred to as smart interface circuit(s). The two interface circuits may have some overlapping circuits/transistors and therefore may be regarded as a single interface circuit.

In some examples, a device may comprise a power transistor (HEMT) described herein, and a control terminal operatively connected to the gate terminal, or the first gate terminal and the second gate terminal. In some examples, the control terminal may be operatively connected to the gate terminal(s) via the interface circuit(s) described herein.

In some examples, the first gate terminal may be connected to the second gate terminal via a potential divider. In some examples, first gate terminal may be connected to the top of the potential divider while the second gate terminal may be connected to a midpoint of the potential divider.

For example, the first gate terminal and the second gate terminal may be connected through a resistive potential divider comprising an upper resistor and a lower resistor, or a potential divider comprising two D-HEMT or two E-HEMT low power transistors (referred to as an upper transistor and a lower transistor) in series. The drain of the upper transistor may be connected to the first gate terminal, and the midpoint of the potential divider (e.g. the source of the upper transistor and the drain of the lower transistor) may be connected to the second gate terminal.

In some examples, either the lower resistor or the upper resistor of a potential divider as described herein is may be provided externally, to enable control of the voltage at the second gate terminal in the on-state, and thereby enable a favorable trade-off between the short-circuit endurance of the transistor and the on-state resistance of the transistor. The short-circuit endurance time may depend on specific application requirements and therefore the ability to adjust this or calibrate this through an external component may be desirable.

In some examples, the second gate terminal is connected to the source terminal via an internal metallization (e.g. short-circuited to the source). In this case there will be no two dimensional gas under the second gate terminal in the forward conduction (as the potential drop between the second gate terminal and source is zero and therefore less than a positive threshold voltage). However, there will be a two dimensional electron gas under the second gate terminal in the reverse conduction, enhancing the conduction path in the reverse conduction mode and therefore reducing the losses during such reverse conduction.

In some examples, an interface circuit is operatively connected to the second gate terminal, the interface circuit being configured to reduce a voltage at the second gate terminal in the event of a short circuit across a drain terminal and a source terminal of the power transistor of the power transistor or an overcurrent flowing between the drain and source terminal.

In an example, a sense transistor (e.g. a sense HEMT) is provided in parallel with the power transistor and in series with a sensing load. The sensing load may comprise a first sensing load terminal connected to a source terminal of the sense transistor, and a second sensing load terminal connected to the source terminal of the power transistor. A gate terminal of the sense transistor may be connected to the first gate terminal of the power transistor. A source terminal of the sense transistor (and the first sensing load terminal) may be connected to a gate terminal of an additional low power transistor (e.g. an E-HEMT), the additional low power transistor comprising a drain terminal connected to the second gate terminal of the power transistor and a source terminal connected to the source terminal of the power transistor.

The sensing load is configured such that when an over current or short-circuit event is present, the voltage drop across the sensing load reaches the threshold voltage of the additional low power transistor, which lowers the potential on the second gate terminal of the power transistor, thus decreasing the current through the power transistor.

In some examples, a device comprises an additional short-circuit (and/or overcurrent) detection circuit, which may be configured to sense a short-circuit (and/or overcurrent event) across the source terminal and the drain terminal of the power transistor. Upon detection of the short-circuit (and/or overcurrent event), the short-circuit detection circuit may be configured to transmit a detection signal to a protection circuit (also referred to as a short-circuit and/or overcurrent protection circuit). The protection circuit may be configured to cause the power transistor to turn off or lower its saturation current, and/or to cause a voltage at the gate terminal (or first and/or second gate terminal) to be reduced, upon receipt of the detection signal.

In some examples, any interface circuits, detection circuits, protection circuits, and/or additional transistors may be monolithically integrated with the power transistor (HEMT) described herein, e.g. on a single III-nitride chip.

In some examples of a device described herein, a device may comprise a plurality of interdigitated fingers, each finger comprising a power transistor (HEMT) as described herein. In some examples of a device described herein, a device may comprise a plurality of cells, each cell comprising a power transistor (HEMT) as described herein.

In some examples, the gate terminal (first gate terminal and/or second gate terminal) of the power transistor (HEMT) may be driven with a dedicated driver. The driver may be provided externally, may be packaged separately from the power transistor (HEMT), may be packaged with the power transistor (HEMT), or may be monolithically integrated with the power transistor (HEMT).

### BRIEF DESCRIPTION OF THE DRAWINGS

The present invention will now be described by way of example with reference to the following drawings:

FIG. 1 illustrates an example of a transistor comprising isolation regions according to the present disclosure;

FIG. 2 is a graph showing the lower saturation current exhibited by a transistor according to the present disclosure;

FIG. 3 illustrates an example of a transistor according to the present disclosure in which the doped III-nitride regions of the gate are separated (segmented) by the isolation regions;

FIG. 4 illustrates an example of a transistor according to the present disclosure in which the doped III-nitride regions and the gate terminal are separated (segmented) by the isolation regions;

FIG. 5 illustrates a three-dimensional view of an example of a transistor according to the present disclosure;

FIG. 6 illustrates another example of a transistor according to the present disclosure;

FIGS. 7a and 7b illustrate an example of a transistor comprising two separated gates according to the present disclosure;

FIG. 8 illustrates an example of a transistor according to the present disclosure in which a first gate and a second gate are segmented by different widths;

FIG. 9a illustrates a cross-sectional view of the transistor illustrated in FIG. 8;

FIG. 9b illustrates a three-dimensional view of the transistor illustrated in FIG. 8;

FIG. 10 illustrates an example of a device according to the present disclosure in which the gates of a double gate transistor are driven by interface circuits;

FIG. 11 illustrates an example of a device according to the present disclosure comprising a short-circuit and/or over-current detection circuit;

FIG. 12 illustrates a further example of a device according to the present disclosure comprising a short-circuit and/or over-current detection circuit;

FIG. 13 illustrates an example of a device according to the present disclosure comprising a sensing load resistor;

FIG. 14 illustrates an example of a transistor according to the present disclosure comprising a hexagonal cell;

FIG. 15 illustrates an example of a device according to the present disclosure comprising a plurality of hexagonal cell transistors;

FIG. 16 illustrates an example of a transistor according to the present disclosure in which the isolation regions are located between the gate terminal and the source terminal;

FIG. 17 illustrates an example of a transistor according to the present disclosure in which the isolation regions are provided with the source; and

FIG. 18 illustrates an example of a transistor according to the present disclosure in which the isolation regions are provided in both the source and gate regions.

### DETAILED DESCRIPTION

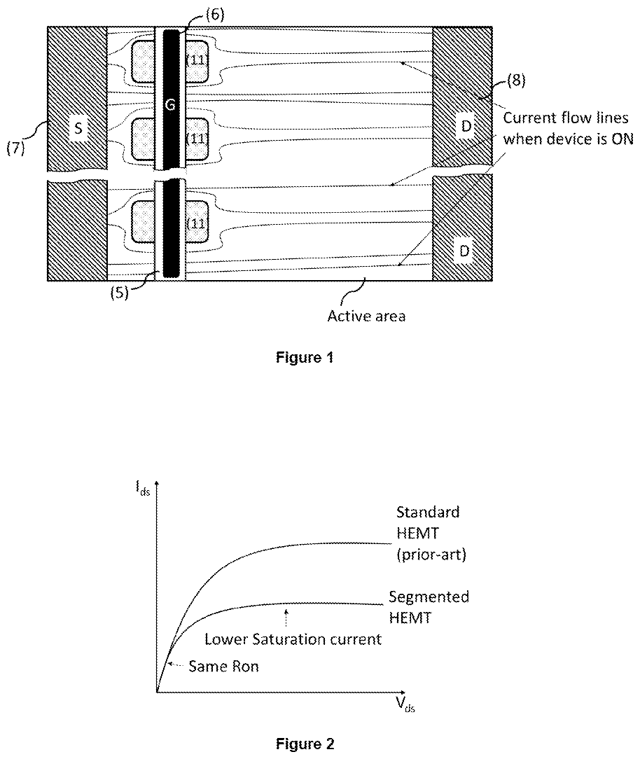

FIG. 1 illustrates an example of a transistor (e.g. a high electron mobility transistor, HEMT), also referred to herein as a “power transistor”, or “power HEMT” according to the present disclosure. In the examples described and illustrated herein, the transistor is a HEMT, but other types of transistor may also be suitable.

As shown in FIG. 1, a gate terminal 6 is formed as a metal layer disposed on a doped III-nitride region (in this case a p-GaN layer 5). The metal layer could form a Schottky or ohmic contact to the p-GaN layer. In some examples, the gate terminal 6 and the p-GaN may be collectively referred to as a gate, or a p-GaN gate.

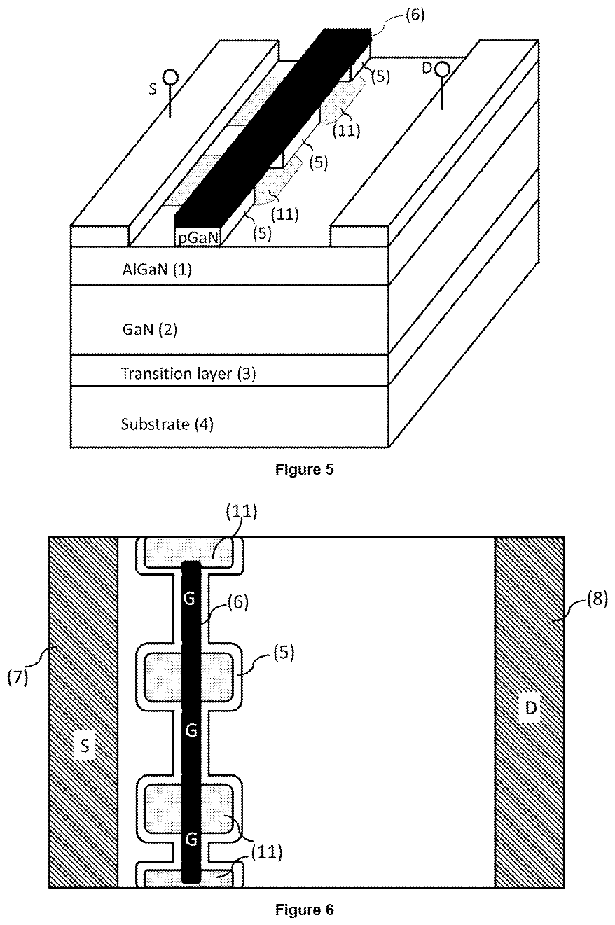

The gate terminal 6 (gate) is disposed between a source terminal 7 and a drain terminal 8. The source terminal 7, drain terminal 8, and gate terminal 6 are spaced apart (in a first direction, or first dimension) and operatively connected to an active area, defined as an area of the transistor where a two-dimensional carrier gas (in the case of the examples described herein, a two-dimensional electron gas, 2DEG) can be formed during at least one mode of operation of the HEMT (e.g. during an on-state). The active area is defined by a heterojunction formed between two III-nitride layers, e.g. between a GaN layer and an AlGaN layer, where a 2DEG is formed. An example of such a heterojunction is illustrated in more detail in FIG. 5, described below.

The limits of the active area region may be defined by an isolation region which surrounds the perimeter of the active area region.

The transistor illustrated in FIG. 1 also comprises a plurality of isolation regions 11 (also referred to herein as “islands”). Such regions could be placed inside the shape of the active area, creating regions of no active area.

The isolation regions 11 are regions where no 2DEG is present in any mode of operation, i.e. regions where the two-dimensional carrier gas is prevented from forming. The isolation regions 11 may comprise doped regions, and/or the isolation regions 11 may comprise etched trenches filled with one or more passivation layers (e.g. oxides and/or nitrides). In the case of etched trenches, the etched trenches may be formed in the transistor down to below the AlGaN/GaN interface (the interface between the two III-nitride semiconductor layers forming the heterojunction).

The isolation regions 11 are formed within (i.e. inside a boundary of) the active area. That is, the isolation regions 11 may interrupt the active area.

As shown in FIG. 2, a transistor according to the present disclosure (which may be referred to as a “segmented HEMT”, although it will be understood that similar benefits are observed for a HEMT of the kind illustrated in FIG. 1) can deliver a lower saturation current (at the same gate voltage) in spite having similar on-state resistance. Moreover the device can benefit from an enhanced reverse conduction and better thermal dissipation. Furthermore, given the reduction in the gate-drain and gate-source capacitances, the device can benefit from good transient performance and higher dV/dt immunity.

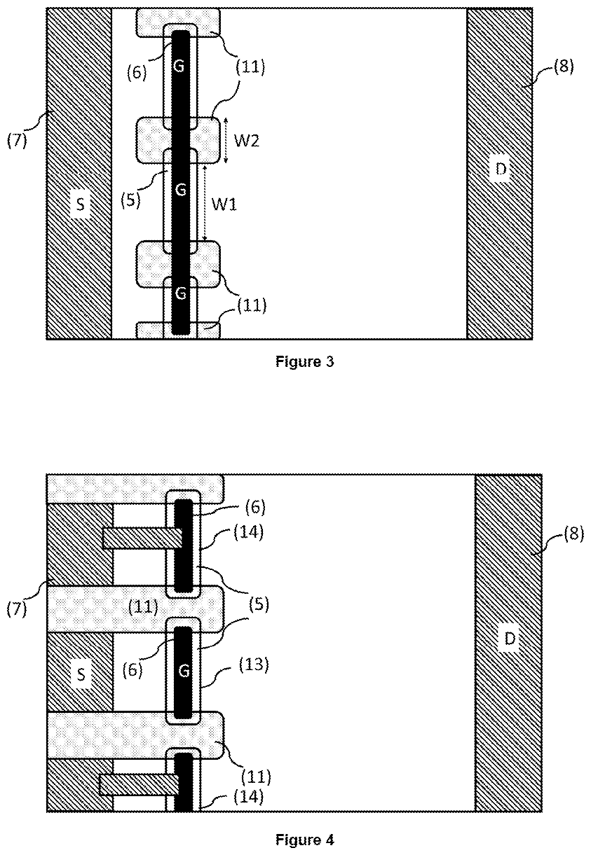

In the transistor shown in FIG. 1, the p-GaN region 5 is continuous. FIG. 3 illustrates an example of a transistor according to the present disclosure in which the p-GaN regions 5 are segmented by isolation regions 11, but the p-GaN regions 5 are all connected to a common gate terminal 6. That is, the isolation regions 11 are between the p-GaN regions 5.

The isolation regions 11 could be formed such that the “active area” is not present in these regions (i.e. the isolation regions 11 may interrupt the active area). The gate width is now a fraction of the total width. The saturation current will be approximately proportional with the effective gate width. Given the effective gate width (gate perimeter) is smaller than the total width (total perimeter), the saturation current can be diminished improving the short-circuit capability of the device (transistor). Moreover, the saturation current level can be adjusted by the segmentation of the gate in a second dimension, perpendicular to the first dimension (the ratio of the active gate 13 width vs total width). The reduction of gate width results in a direct reduction of the saturation current. It also results in a non-proportional increase in the on-state resistance. This is because the on-state resistance is largely made of the channel resistance plus the drift resistance. For a high voltage device, in the linear region of operation and at relatively high gate voltages, the channel resistance is smaller than the drift resistance. For example, if the gate width is half of the total width the saturation current can be approximately cut to half with only 20% (an estimate) increase in the total on-resistance. To compensate for the decrease in the on-state resistance, the active area of the device can be increased by 20% and still delivering an overall smaller saturation current as shown in FIG. 2. Moreover, during the reverse conduction a 2DEG could be present at the heterojunction under the p-GaN sections which are connected to the source 7 and this 2DEG can contribute to reverse conduction, cutting the losses during the reverse conduction. Such a structure is particularly beneficial in high power topologies (half bridges) where short-circuit capability and reverse conduction are important. The larger area chip could also help to achieve a better thermal dissipation. Furthermore given the reduction in the gate width (gate perimeter), the gate-to-drain Miller capacitance (C_{gd}) and the gate-to-source capacitance (C_{gs}) can be reduced. This is really beneficial in cutting transient losses and reducing the effect of the dV/dt displacement currents through the Miller capacitance.

As shown in FIGS. 1 and 2, the isolation regions 11 are in the form of closed islands. The isolation regions 11 may have a circular, or at least rounded (e.g. rounded corners) shape, which may assist with the current spreading from the channel into the drift region and avoid any possible concentration of current flow lines or high electric fields. The p-GaN gates are overlapping the isolation regions 11, such to supress any 2DEG path between the source 7 and drain 8 terminals when the gate is off. Note that a common metal layer can connect all segmented gate regions to the same gate terminal.

Preferably (with reference to FIG. 3), the width of the isolation region 11, W2, (in the second direction) should be smaller than the length of the drift region (in the first direction). The drift region length is the distance from the gate to the drain (L_{gd}). W2 should be smaller than Lgd so that spreading of the current from the active gate 13 can be more effective. If W2 is larger than L_{gd} the drift region resistance would be significantly increased too due to poor spreading of the current through the part of the drift region which is adjacent to the isolation regions 11. The smaller W2, the smaller the effect of the segmentation on the drift region resistance. W1 is the distance between isolation regions 11.

FIG. 4 illustrates an example of a transistor according to the present disclosure in which the p-GaN regions 5 and the gate terminal 6 are segmented by the isolation regions 11 (i.e. the isolation regions 11 are in between the p-GaN regions 5 and the respective sections of gate terminal 6). A set of sections (13) of p-GaN region 5 are connected to the gate terminal 6 forming the active gate, other sections 14 of p-GaN region 5 are connected to ground.

FIG. 5 illustrates a three-dimensional view of another example of a transistor according to the present disclosure (for example, the transistor illustrated in FIG. 5 may correspond to some implementations of the example illustrated in FIG. 3). Also illustrated in FIG. 5 are the AlGaN layer 1 and the GaN layer 2 that form the heterojunction. The transistor is formed on a substrate 4 (e.g. a silicon wafer), and a transition layer 3 separates the substrate 4 from the heterojunction layers. The transition layer 3 may be used to allow a high quality GaN layer 2 to be grown despite the significant lattice mismatch between GaN and Si. Other types of substrates can be used such as sapphire and semi insulating silicon carbide. For such substrates the transition layer may not be needed as the sapphire and the silicon carbide have a similar lattice constant with GaN.

FIG. 6 illustrates another example of a transistor according to the present disclosure, in which the p-GaN region 5 surrounds the isolation regions. This may be advantageous, as 2DEG layers will be formed under the p-GaN region around the edges of the isolation regions (but still within the active area). This would facilitate current spreading into the drift region and avoid current crowding near the edges of the isolated regions.

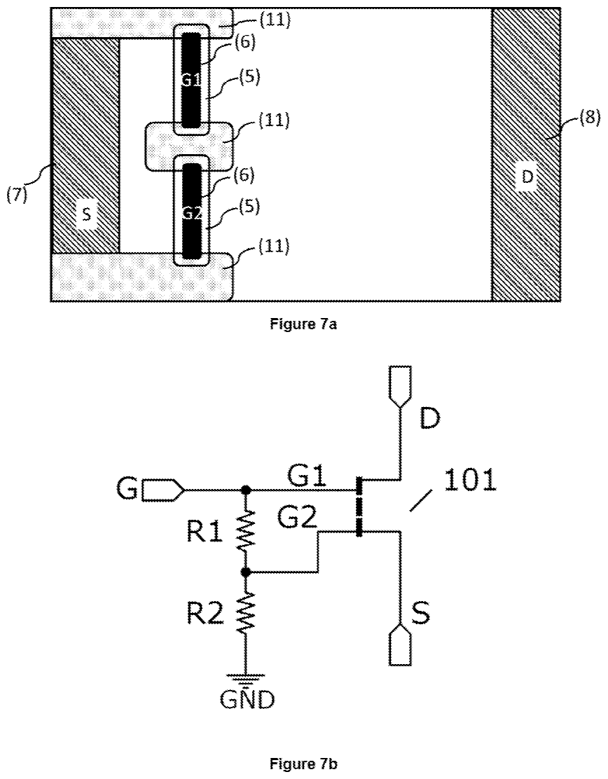

FIGS. 7a and 7b illustrate another example according to the present disclosure, comprising a “double gate” transistor 101. G1 and G2 are separated gates, further isolated from each other by the isolation regions 11. The gates G1, G2 could be operated in three configurations: (1) one gate is active in forward conduction and other is grounded; or (2) both gates are simultaneously active through a potential divider in forward conduction; or (3) one gate is active in forward conduction and one gate is active in reverse conduction.

The gate terminal 6 of the gate G1 may be referred to as a first gate terminal, and the gate terminal 6 of the gate G2 may be referred to as a second gate terminal.

According to configuration (1) in forward conduction, when the drain potential is above the source potential, G1 is active (meaning 2DEG is formed underneath, upon an application of G1 to source voltage above a threshold voltage) and G2 is grounded (no 2DEG is formed underneath) leading to a reduction in saturation current compared to a device with the same dimension with a single continuous (i.e. non-segmented) gate. In reverse conduction, when the source potential is above the drain potential and both gates are at the same potential as the source, at certain source to drain voltage, a 2DEG is formed under both gates. In this configuration, the device could benefit from both good forward and reverse conduction. Given that 2DEG is present under Gate 2 in the reverse conduction, the losses would be very low. Note that in forward conduction, the device benefits from lower saturation current (as G2 is grounded) and hence ensuring good short-circuit capability.

Alternatively, the gates G1, G2 can be driven in configuration (2) as shown in FIG. 7b. The gates could be connected through a potential divider—where the resistances could be for example as part of a Miller clamp. Alternatively, the resistances could be provided externally. For example, the lower resistance in the potential divider could be adjusted externally to adjust the potential on G2 and therefore the trade-off between short circuit performance (i.e. withstand time in a short circuit condition) and on-state resistance could be achieved.

The advantage of decoupling G2 and G1, is that a good trade-off can be obtained between the on-state resistance and the short-circuit capability. The G1 voltage could be temperature dependent. This could be achieved by having an interface in front of the gate. At low temperature, (for example <0° C.), G1 voltage bias could be lower than at room temperature but still in excess of the threshold voltage. The G2 voltage could be very low at low temperatures, close or below the threshold voltage. Both voltages on G1 and G2 could increase as temperature is increased, but the potential on G2 could be kept relatively low when compared to G1 (e.g. 2-4V lower) to deliver an overall lower saturation current (in comparison to the case where all the gate segments would be biased at the same voltage bias as G1).

Therefore in configuration (2), G1 could be driven to a higher voltage while G2 could be driven to a lower voltage. The configuration has the advantage of having a good trade-off between low on-state resistance and relatively low saturation current. The voltages at G1 and G2 could be temperature dependent.

The interface, to drive or partially drive or interface to G1 and G2 can be monolithically integrated with the power HEMT or can be provided in a separate chip, which preferably could be made in silicon. In the latter case the two chips could be provided separately in the same package.

Configuration 3 is similar to configuration 2 but offers an even better reverse conduction. In this configuration, in the forward conduction, when the drain potential is above the source potential, G1 is active (meaning 2DEG is formed underneath, upon an application of G1 to source voltage above a threshold voltage) and G2 is grounded (no 2DEG is formed underneath). In reverse conduction, when the source potential is above the drain potential, G2 is active and G1 is grounded. A 2DEG is provided under G2 at a lower source to drain voltage. Eventually a 2DEG will be formed under G1 too at a slightly higher source to drain voltage. In this configuration, the device could benefit from both good forward and reverse conduction. Compared to configuration 2, the resistance in the reverse conduction will be further reduced, but at the expense of a more difficult drive circuit. Note that in forward conduction, the device benefits from lower saturation current (as G2 is grounded) and hence ensuring good short-circuit capability.

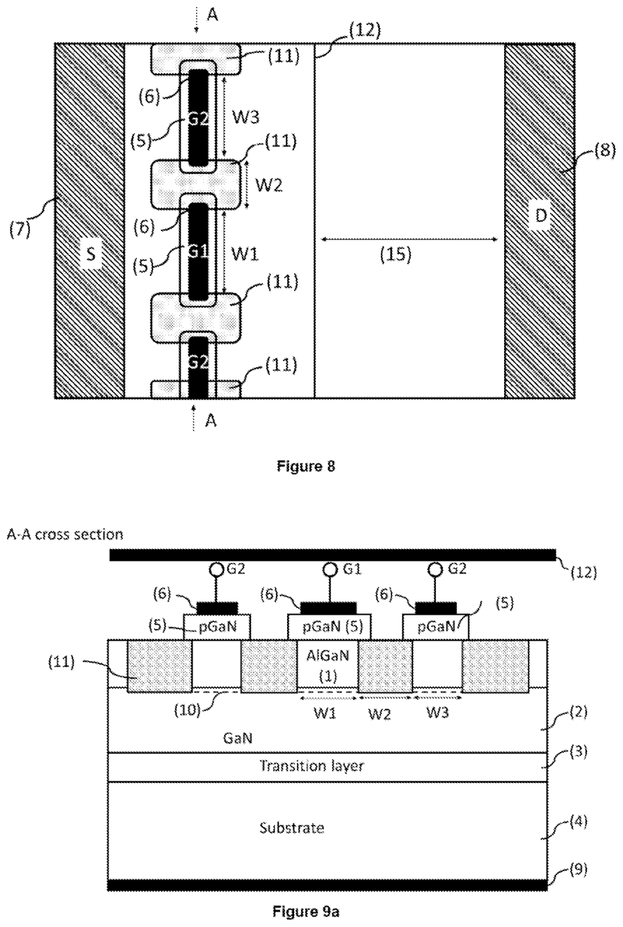

FIG. 8 illustrates an example in which the two gates G1, G2 can be segmented by different widths, identified as W1. If the configuration shown in FIG. 7b is chosen, the saturation current will depend linearly and more strongly on W1/(W1+w2+W3) rather than on W3/(W1+W2+W3). The greater the W2, the lower the saturation current. The end of the field plate is shown in FIG. 8. The field plate could be connected to the source terminal via one of the upper metal layers. As previously, W2 is preferably smaller than the distance between the drain-side end of the field plate close to the gate side and the drain shown in FIG. 8 as (15). As a numerical example for a 600V rated device, W2 could be 4 μm, W3 could be 4 μm, and W1 could be 6 μm while (15) could be between 7 μm to 15 μm.

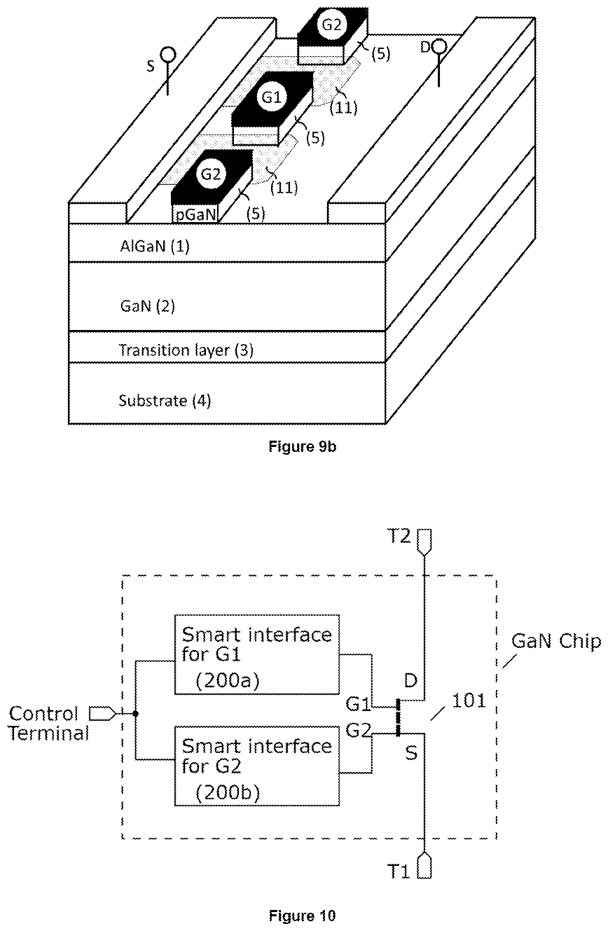

FIG. 9a illustrates the cross section A-A of FIG. 8, and FIG. 9b illustrates a three-dimensional view of the same. The isolation regions 11 (where no 2DEG is present), are shown as filled trenches as described above. Between the isolation regions 11, segmented gates G1 and G2 are present. Under G1 and G2, a 2DEG can be present, but their charge could be modulated separately (or through a potential divider) by the potentials applied to G1 and G2 respectively.

FIG. 10 shows that a double gate transistor 101 according to the present disclosure, shown schematically in FIGS. 5-7, can be driven with dedicated smart interface circuits 200a, 200b which can be integrated alongside the transistor 101 within the same GaN chip. Externally the interface circuits 200a, 200b can be connected to a same gate terminal (control terminal). A DC supply voltage to both interface circuits 200a, 200b (VDD) can be present (not shown). Alternatively, the interface circuits 200a, 200b can be part of an external silicon chip and co-packaged with the double GaN HEMT device 101. Alternatively, a single smart interface circuit is provided (instead of the two circuits) with two distinctive outputs to G1 and G2 (not shown).

FIG. 11 illustrates the double gate transistor 101 with a short-circuit (SC) and/or over current detection circuit 300 provided and a feedback loop to the smart interface circuit 200b driving G2. The SC or over current detection circuit 300 has been described in U.S. patent application Ser. Nos. 18/394,141 and 18/394,078, the contents of which are hereby incorporated by reference.

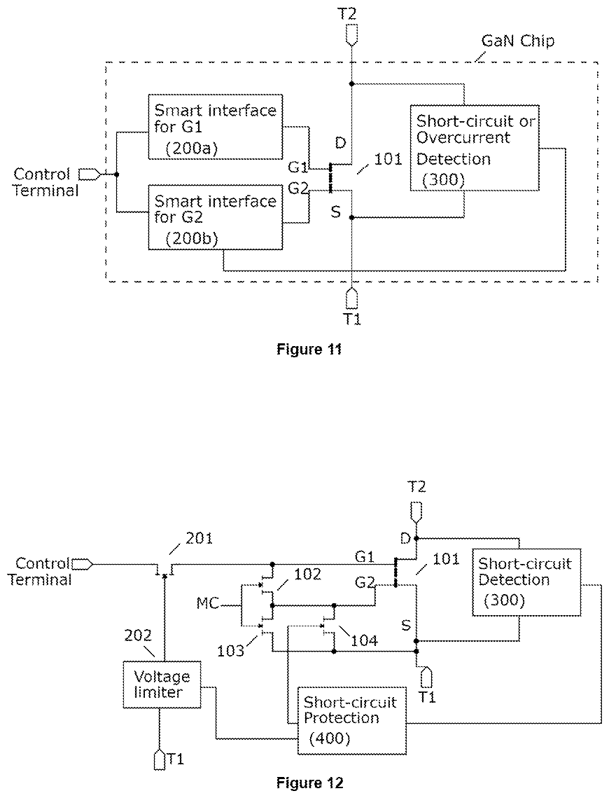

FIG. 12 illustrates a double gate transistor 101 with a short-circuit (SC) detection (or over current (OC) detection) circuit 300 and an SC protection (or OC protection) circuit 400. When an SC or OC event is detected, a signal is given by the detection circuit 300 to the protection circuit 400 which acts on the gate of a low-power HEMT 104 to pull G2 to a lower potential or to the same potential as the source. The effect is that of a feedback reaction to a SC or OC event which ensures a rapid decrease of the drain-source current. Note that G1 would still be active but the current through the 2DEG channel modulated by G2 would be decreased or suppressed. G1 and G2 are arranged in a potential divider through a Miller clamp MC (pull-down device). The Miller clamp MC is represented here through two transistors 102, 103, with the upper voltage connected to G1 and the midpoint connected to G2.

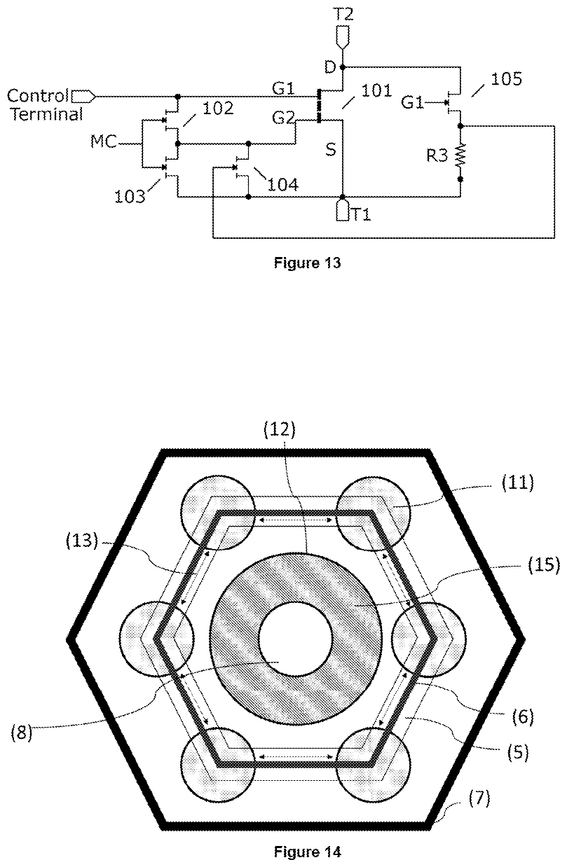

FIG. 13 illustrates a double gate device with a sense HEMT 105 featuring a gate connected to G1 of the main HEMT 101. A sensing load resistor R3 could be connected internally or externally to the source of the sense HEMT 105. The upper node of the resistor R3 is connected to the gate of a low-power HEMT 104. In case of an over-current event or short-circuit event, the resistance is chosen so that the voltage drop across the resistor R3 exceeds the threshold voltage of the low-power HEMT 104. In this case, the low-power HEMT 104 turns on, lowering the G2 potential, ideally closer to that of the source. This results in a decrease or suppression of the current through the G2 gates, when the transistor 101 or device is in short-circuit or experiences an over current event. As a result, the current between the drain-source is decreased offering an enhanced endurance to short-circuit or over-current events.

FIG. 14 illustrates another example according to the present disclosure. A hexagonal cell (also referred to as a hex cell) is provided with the source metallization ring 7 running on the outside and the drain metallization 8 in the centre of the hex cell, in a circular shape. The source/drain field plate edge 12 may also have a circular shape so that the lateral electric field is confined between the circular edge of the source/drain field plate and the circular edge of the drain (or drain field plate). A p-GaN gate 6 has a hexagonal ring shape and the source metallization 7 has also a hexagonal ring shape and provided on the outside of the p-GaN gate 6. The device may incorporate any closed-loop shape design for source and the gate-hex, circular, flower etc and a circular drain (or regular polygon with more than 6 corners and angles larger than 120 degrees). Isolation regions 11 may be provided to segment the hexagonal gate 6. In FIG. 14, the isolation regions 11 are located at the corners of the hexagonal p-GaN gate 6. The dimensions of these isolation regions 11 adjust the trade-off between the saturation current (short-circuit capability) and the on-state resistance of the structure. The larger these isolation regions 11 are, the lower the perimeter of the active gate 13 and therefore the lower the saturation current and hence the better the short-circuit endurance. However, if the remaining perimeter of the active gate 13 is too small, the channel resistance would be increased leading to too high on-state resistance. The isolation regions 11 can be located at other positions (i.e. not necessarily at the corners of the gate 6). Other possible placements of the isolation regions 11 may include: on the sides of the p-GaN hexagon, or between the gate hexagon and the source hexagon or on the corners of source hexagon, thus increasing the source resistance. An increased source resistance also results in a lower saturation current and therefore improved short-circuit endurance.

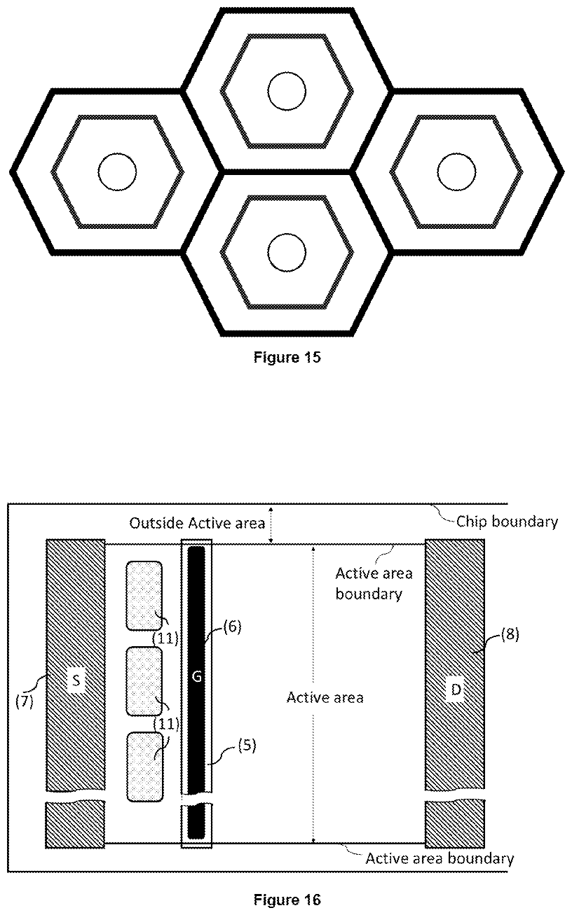

FIG. 15 illustrates an example of a device in which several cells as shown in FIG. 14 are connected together. The hex structure offers an increased packing density and therefore a higher perimeter of the channel for a given area than an inter-digitated design. The sources could be connected with a lower metal layer in a mesh of hexes. The drain could be connected to an upper metal and interdigitated with the source upper metal.

FIG. 16 illustrates another example according to the present disclosure, in which the isolation regions 11 are located between the gate 5, 6 and the source 7, which may increase the series source resistance. The increase in the series source resistance is a very effective way to decrease the saturation current and thus increase the short-circuit endurance. The current has to flow through the isolation regions 11, resulting in an increase in the series source resistance. As shown in FIG. 16, the active area boundary of the power transistor is within the overall chip boundary. The region between the active area boundary and the chip boundary (“outside active area”) may be defined by a boundary isolation region as described above.

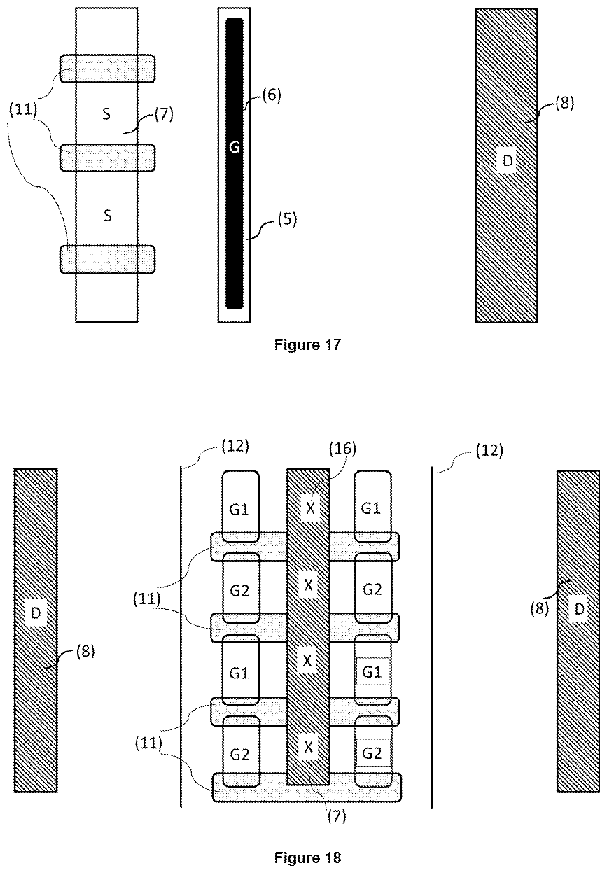

FIG. 17 illustrates an alternative design to FIG. 16, where the isolation regions are provided within the source itself, leading to a more compact design. The contact 16 to the source is represented by squares labelled X. The effect is the same, i.e. an increase in the series resistance of the source, leading to lower saturation current and enhanced short-circuit endurance.

FIG. 18 illustrates an alternative design in which the isolation regions 11 are provided both in the source and gate regions leading to both a lower effective gate perimeter and a higher series source resistance. The design shown here incorporates two gate G1 and G2, however the same approach can be applied to a transistor with a single gate G.

Although the description of the present invention has focused primarily on p-type GaN gates (e.g. GaN doped with magnesium), aspects of the present invention may also apply to Schottky gates, Ohmic p-type GaN gates or insulated gates. In case of insulated gates other names for the HEMT could be used as MISFETs (Metal Insulated Semiconductor Field Effect Transistors).

It will also be appreciated that terms such as “top” and “bottom”, “above” and “below”, “lateral” and “vertical”, and “under” and “over”, “front” and “behind”, “underlying”, etc. may be used in this specification by convention and that no particular physical orientation of the device as a whole is implied.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in the disclosure, whether alone or in any appropriate combination with any other feature disclosed or illustrated herein.

### REFERENCES

[1] https://www.powerelectronicsnews.com/ultrafast-discrete-short-circuit-protection-for-gan-hemts
[2] https://ieeexplore.ieee.org/document/9861995

1. A power transistor comprising:
a source terminal;
a drain terminal;
a gate terminal;
a heterojunction formed between two III-nitride semiconductor layers, the heterojunction being configured to allow the formation of a two-dimensional carrier gas at the heterojunction and thereby define an active area of the power transistor; and
a plurality of isolation regions located inside a boundary of the active area, the plurality of isolation regions being configured to prevent the formation of the two-dimensional carrier gas inside the plurality of isolation regions;
wherein the source terminal, the drain terminal, and the gate terminal are laterally spaced apart in a first direction, the gate terminal being located between the source terminal and the drain terminal; and
wherein the isolation regions are spaced apart from one another in a second direction, perpendicular to the first direction.

2. A power transistor according to claim 1, wherein a distance between adjacent isolation regions in the second direction is smaller than a distance between the drain terminal and the gate terminal in the first direction.

3. A power transistor according to claim 1, wherein the isolation regions are adjacent the gate terminal of the power transistor.

4. A power transistor according to claim 1, wherein the isolation regions are between the source terminal and the gate terminal of the power transistor.

5. A power transistor according to claim 1, wherein the isolation regions are adjacent the source terminal of the power transistor.

6. A power transistor according to claim 1, wherein the isolation regions comprise trenches formed in the III-nitride semiconductor layers, the trenches being filled with dielectric material.

7. A power transistor according to claim 1, wherein the isolation regions comprise doped regions configured to inhibit the formation of a two dimensional carrier gas.

8. A power transistor according to claim 1, comprising a doped III-nitride region disposed within the boundary of the active area, wherein the gate terminal is disposed on the doped III-nitride region.

9. A power transistor according to claim 1, comprising a plurality of doped III-nitride regions disposed within the boundary of the active area and separated by the isolation regions, wherein the gate terminal is disposed across the plurality of doped III-nitride regions.

10. A power transistor according to claim 1 comprising a hexagonal cell, wherein:
the source terminal is a hexagonal source terminal; and
the gate terminal is a hexagonal gate terminal; and
wherein the hexagonal source terminal, the hexagonal gate terminal, and the drain terminal surround a same axis.

11. A power transistor according to claim 10, wherein the isolation regions are located at corners of the hexagonal gate terminal.

12. A power transistor according to claim 10, wherein the isolation regions are located at corners of the hexagonal source terminal.

13. A power transistor according to claim 1, wherein the gate terminal is a first gate terminal, and wherein the power transistor further comprises a second gate terminal;
wherein at least one of the isolation regions is between the first gate terminal and the second gate terminal.

14. A power transistor according to claim 13, wherein the first gate terminal is operatively connected to a first gate of the power transistor, and wherein the second gate terminal is operatively connected to a second gate of the power transistor;
wherein the first gate is configured to operate with a gate-source potential above a threshold voltage of the power transistor when a potential at the drain terminal is higher than a potential at the source terminal and the power transistor is in a forward on-state; and
wherein the second gate is configured to be grounded or to operate with a gate-source potential above the threshold voltage of the power transistor when the potential at the drain terminal is lower than the potential at the source terminal and the power transistor is in a reverse on-state.

15. A device according to claim 14, wherein the first gate terminal is connected to the second gate terminal via a potential divider, wherein the second gate terminal is connected to a midpoint of the potential divider.

16. A device according to claim 14, further comprising:
an interface circuit operatively connected to the second gate terminal, the interface circuit being configured to reduce a voltage at the second gate terminal in the event of a short circuit or overcurrent across a drain terminal and a source terminal of the power transistor.

17. A high electron mobility transistor (HEMT) comprising:
an active area comprising a III-nitride heterojunction, the heterojunction being configured to allow the formation of a two-dimensional carrier gas at the heterojunction;
a source terminal operatively connected to the active area;
a drain terminal operatively connected to the active area;
a first p-type doped III-nitride region and a second p-type doped III-nitride region, the first and second doped III-nitride regions being disposed within a boundary of the active area;
a first gate terminal disposed on the first doped III-nitride region; and
a second gate terminal disposed on the second doped III-nitride region;
wherein the first and second doped III-nitride regions are separated by an isolation region, the isolation region being configured to prevent the formation of the two-dimensional carrier gas inside the isolation region.

18. A HEMT according to claim 17, wherein the source terminal and the drain terminal are laterally spaced apart in a first dimension, and wherein the first and second doped III-nitride regions are laterally spaced apart in a second dimension.

19. A HEMT according to claim 17, wherein the first gate terminal is connected to the second gate terminal via a potential divider, wherein the second gate terminal is connected to a midpoint of the potential divider.

20. A device comprising a HEMT according to claim 17, the device further comprising an interface circuit operatively connected to the second gate terminal, the interface circuit being configured to reduce a voltage at the second gate terminal in the event of a short circuit or overcurrent across the drain terminal and the source terminal.
